(19) United States
(12) Patent Application Publication
(10) Pub. No.: US 2008/0278353 A1
(43) Pub. Date: Nov. 13, 2008

(54) TAMPER RESISTANT ELECTRONIC TRANSACTION ASSEMBLY

(75) Inventors: Peter R. Smith, Folsom, CA (US); Susan H. Zaks, Carlsbad, CA (US)

Correspondence Address: Howard IP Law Group, P.O. Box 226, Fort Washington, PA, 19034, US

(73) Assignee: MEASUREMENT SPECIALTIES, INC., Hampton, VA (US)

(21) Appl. No.: 12/118,294

(22) Filed: May 9, 2008

Related U.S. Application Data
(60) Provisional application No. 60/928,902, filed on May 11, 2007.

(51) Int. Cl. H03K 17/94; G06F 3/02

(52) U.S. Cl. 341/22; 345/168

(57) ABSTRACT

A tamper resistant user interface device includes a substantially planar sensor. The sensor includes a plurality of user activated membrane switches. At least one multilayer structure is folded around and overlays the planar sensor. The structure includes at least one layer to detect tampering with the sensor.

### CROSS REFERENCE TO RELATED APPLICATION

The present application claims the benefit of U.S. Provisional Application Ser. No. 60/928,902, entitled TAMPER RESISTANT ELECTRONIC TRANSACTION ASSEMBLY, filed May 11, 2007, which application is incorporated by reference herein in its entirety.

### FIELD OF THE INVENTION

The present invention relates generally to user interface devices used to enter secret information, such as keyboards and keypads, used to enter passwords and personal identification numbers (PINS).

### BACKGROUND OF THE INVENTION

There are instances when a user must enter an item of secret information, such as a password or a personal identification number (PIN). For example, consumer-related electronic financial transactions are commonplace. Examples include point-of-sale (POS) electronic transactions, PIN entry devices (PED), and automated teller machine (ATM) transactions. Such transactions often utilize a user account card, such as credit or debit card. Such a card typically incorporates a magnetic stripe, microcontroller chip, or other data storage means, that is automatically read by a card reader. The present invention will be discussed as it relates to a card incorporating a magnetic stripe by way of non-limiting example only.

In certain transactions, a user is required to enter a personal identifier, such as a conventional personal identification number (PIN). This is particularly prevalent with debit card transactions. The present invention will be further discussed as it relates to PINs, by way of non-limiting example only.

Referring now to FIG. 1, there is shown a perspective view of a POS magnetic stripe card reader 10, which features a magnetic card swipe slot 20, a keypad 30 and a display 40. Reader 10 conventionally operates in conjunction with a POS terminal, such as an electronic cash register. To process a transaction, such as a purchase or refund, a magnetic stripe card is passed through slot 20 to recover data indicative of a user account. The card holder is then prompted to enter his PIN using keypad 30. The recovered data and entered PIN are then transmitted for processing.

Referring now to FIG. 2, there is shown a perspective view of an automated teller machine (ATM) 15. ATM 15 also includes a magnetic card swipe slot 20, a keypad 30 and a display 40. To process a transaction, such as to withdraw cash from a bank account, a magnetic stripe card is swiped through slot 20 to recover data indicative of a bank account. The card holder is then prompted to enter his PIN using keypad 30. The recovered data and entered PIN are again transmitted for processing.

The illustrations of FIGS. 1 and 2 are by way of example only, and are not intended to limit the present invention. Indeed, embodiments of the present invention are suitable for use with a wide variety of devices.

Consumer electronic financial transactions that utilize entered PINs may be prone to fraud. For example, a card holder may feel secure using a magnetic swipe card because he believes the corresponding PIN must be known in order to use the card. As long as the card holder adequately safeguards the PIN, he might assume that the accounts associated with the swipe card are also secure. Substantial efforts have been made to protect recovered account data and entered PIN data transmitted for processing.

However, it may be possible to acquire a user's PIN by tampering directly with the user interface device used to enter the PIN, such as keypad 30. For example, it may be possible to tamper with a keypad, by providing additional connections thereto, for purposes of acquiring entered PINs. Accordingly, a tamper-resistant keypad for use with point-of-sale (POS) electronic transaction machines, a PIN entry device (PED), and/or automated teller machines (ATMs) is desirable.

“Tamper-resistance”, as used herein, generally includes tamper-evidencing and tamper resisting. For example, an assembly that evidences that a keypad has been tampered with, electronically and/or otherwise, provides for tamper resistance. Further, an assembly that facilitates the de-activation of a key-pad incorporating device responsively to keypad tampering also provides tamper resistance.

### SUMMARY OF THE INVENTION

An embodiment of the invention is a tamper resistant user interface device including a substantially planar sensor. The sensor includes a plurality of user activated membrane switches. At least one multilayer structure is folded around and overlays the planer sensor. The multilayer structure includes at least one layer to detect tampering with the sensor. In an embodiment of the invention, the sensor is in the form of a keyboard or a keypad.

Another embodiment of the invention is a circuit for detecting tampering with a sensor. The circuit includes a first and second drill layers on either side of a substantially planar sensor and first and second electrical leads connected to the first and second drill layers respectively. The circuit also includes first and second serpentine conductive layers adjacent to the first and second drill layers respectively and third and fourth electrical leads connected to the first and second serpentine conductive layers respectively. The circuit further includes a fifth electrical lead connected between the first and second conductive layers. Peel-type tampering is detected by checking continuity between the third and the fifth leads and between the fourth and the fifth leads. Penetration-type tampering is detected by checking for electrical shorts between the first and the second leads connected to the first and the second drill layers.

Another embodiment of the invention includes a method for detecting tampering with a sensor. The method includes a step of checking for electrical shorts between first and second electrical leads coupled to first and second drill layers laid on either side of a substantially planar sensor and a step of checking for a break in continuity between third and fourth electrical leads and between fifth and fourth electrical leads. The third and fifth electrical leads are electrically coupled across first and second conductive layers adjacent to the first and second drill layers respectively and the fourth electrical lead is coupled between the first and second conductive layers.

### BRIEF DESCRIPTION OF THE FIGURES

Understanding of the present invention will be facilitated by consideration of the following detailed description of the preferred embodiments of the present invention taken in conjunction with the accompanying drawings, in which like numerals refer to like parts and in which:

FIG. 1 illustrates a point-of-sale magnetic card reader;

FIG. 2 illustrates an automated teller machine;

FIG. 3 illustrates a point-of-sale magnetic card reader according to an embodiment of the present invention;

FIG. 4 illustrates a tamper resistant user interface suitable for use as the keypad in the point-of-sale magnetic card reader of FIG. 3;

FIG. 5 illustrates a circuit configuration suitable for use with the tamper resistant user interface of FIG. 4;

FIG. 6 illustrates a multi-layer structure suitable for use as one or more of the tamper resistance layers of the tamper resistant user interface of FIG. 4;

FIGS. 7-14 illustrate configurations suitable for use as the layers of the multi-layer structure of FIG. 6;

FIG. 15 illustrates electrical configuration of the layers of FIG. 6, according to an embodiment of the present invention;

FIG. 16 illustrates a cross-section view of a tamper resistant membrane switch keypad assembly according to an embodiment of the present invention; and,

FIGS. 17a, 17b, 17c and 18-21 illustrate configurations suitable for use as components of the assembly of FIG. 16.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, many other elements found in typical user interface, keypad, keyboard, POS and ATM systems. However, because such elements are well known in the art, and because they do not facilitate a better understanding of the present invention, a discussion of such elements is not provided herein. The disclosure herein is directed to all such variations and modifications known to those skilled in the art.

A tamper resistant user interface device according to an embodiment of the present invention includes: a substantially planar sensor including a plurality of user activated membrane switches; and, a multilayer structure adhered to the sensor, wherein the multilayer structure includes at least one layer to frustrate tampering with the sensor. According to an embodiment of the present invention, the sensor may take the form of a keyboard or keypad. According to an embodiment of the present invention, the multilayer structure includes a plurality serpentine conductor layers. According to an embodiment of the present invention, the multilayer structure includes a plurality of substantially planar conductive sheet layers.

Such a tamper-resistant user interface may be used with a wide variety of user-interface incorporating devices, including, by way of example only, POS devices, PED, ATMs and public Internet access devices, such as personal computers. In such a case, a tamper-resistant keyboard may be used to mitigate the risk of keyboard tampering for purposes of illicitly acquiring users' passwords. The present invention will be further discussed as it relates to POS devices and keypads, by way of example.

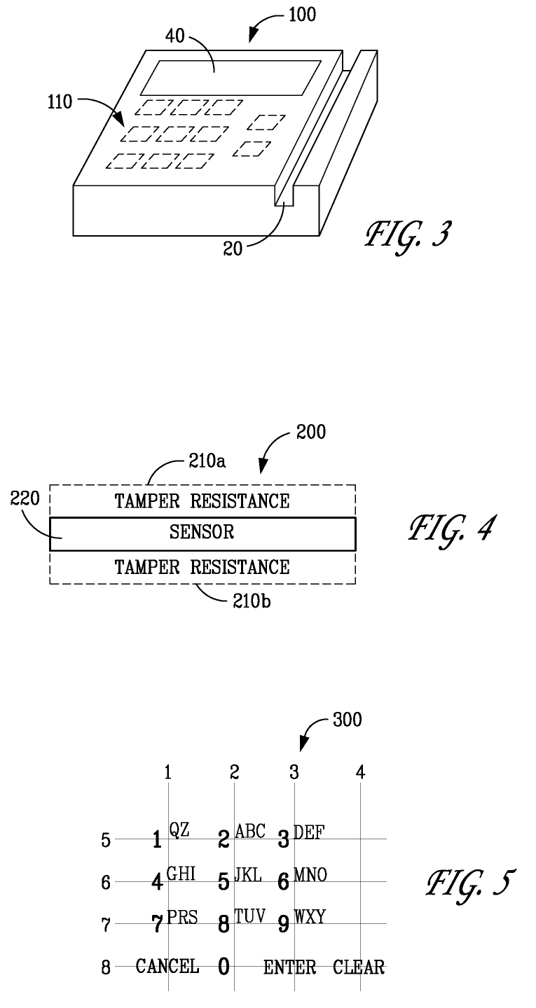

Referring now to FIG. 3, there is shown a perspective view of a POS magnetic stripe card reader 100, which features a magnetic card swipe slot 20, a keypad 110 and a display 40. Like reader 10 (FIG. 1), reader 100 operates in conjunction with a POS terminal, such as an electronic cash register. To complete a transaction, such as a purchase or refund, a magnetic stripe card is swiped through slot 20 to recover data indicative of a user account. The card holder is then prompted to enter his PIN using keypad 110. The recovered data and entered PIN are then transmitted for processing. According to an embodiment of the present invention, keypad 110 is tamper resistant.

A tamper-resistant keypad according to an embodiment of the present invention includes a plurality of stacked conductive and non-conductive layers oriented such that when specific areas of the keypad are pressed with a finger or other implement, an electrical contact is made identifying the location of the pressed area. Additional conductive layers, non-conductive layers and adhesive layers are integrated into the assembly so that attempts to tamper with, circumvent, penetrate, remove, or otherwise breach the keypad in order to gain access to the keypad circuits, or gain access to sensitive hardware, firmware, or software through the surface of the keypad are frustrated. Such frustration may be accomplished through detection and/or keypad deactivation, for example.

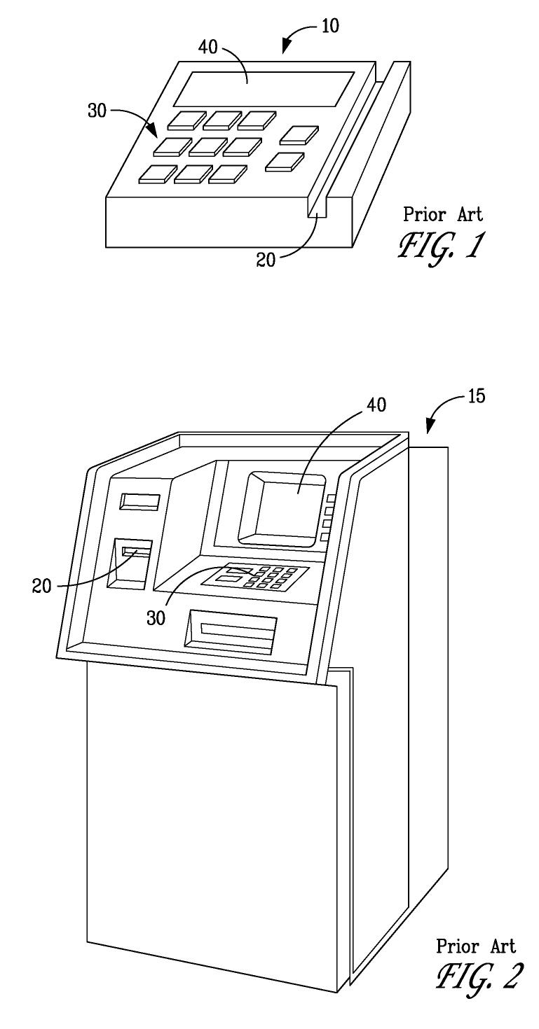

Referring now to FIG. 4, there is shown a view of a tamper resistant keypad 200 according to an embodiment of the present invention. Keypad 200 may include a substantially planar sensor 220, including a plurality of membrane switches. The switches may be configured in an array, for example. Sensor 220 may be provided with tamper resistance layers 210a and/or 210b. Keypad 200 allows a user to enter a PIN in a more secure manner than is conventionally achievable utilizing mechanical switches, such as those shown in FIGS. 1 and 2.

It is understood that a membrane switch is a type of electrical switch and differs from a mechanical switch; for example, a membrane switch may include a circuit printed on a thermoplastic polymer resin, such as Polyethylene terephthalate (PET), for example. The ink used for printing may be composed of a conductive material, such as copper or silver. A membrane switch may typically incorporate from around 2 to around 4 layers. The first layer may be printed with a circuit structure that provides a first contact, while the second layer acts as a spacer and the third layer acts as a second contact. All three layers may be composed of PET, for example. An outer surface of the first or third layer may be printed with visible indicia. Tactile feedback can be provided by embossing the outer-most PET layer, embedding metal snap domes and/or providing an embossed overlay, for example.

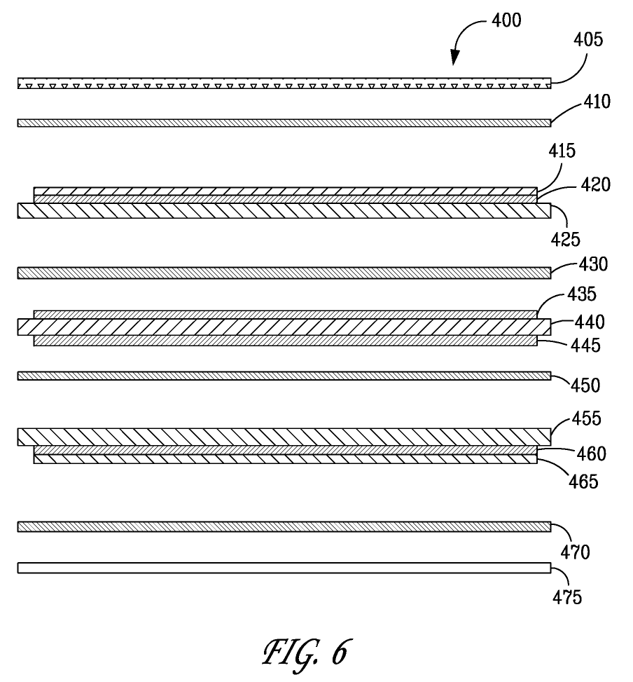

Referring now to FIG. 5, there is shown a schematic-view of a circuit representation 300 of sixteen membrane switches suitable for use with keypad 220. Representation 300 includes 8 leads 300 (1-8). In the exemplary embodiment shown, lead 1 is coupled to lead 5 (by compression of the layers against one-another in a corresponding membrane switch represented by the intersection of the leads), and is indicative of user activation of the corresponding membrane switch—button 1 in the illustrated case. Lead 3 being coupled to lead 8 is indicative of user activation of another corresponding membrane switch—an ENTER button in the illustrated case. Each of the other membrane buttons may be selectively activated and sensed in an analogous manner.

Referring again to FIG. 4, tamper resistance layers 210a and/or 210b may overlay one or both surfaces of membrane-switch keypad 220. Tamper resistance layers 210a, 210b may take the form of structures that evidence penetration- and/or peeling-type tampering. Tamper resistance layers 210a, 210b may be the same or different in terms of material sublayers, and or dimensions. Tamper resistance layers 210a, 210b may each take the form of a multi-layer structure, for example.

According to an embodiment of the present invention, one or more of layers 210a, 210b may incorporate a drill plate. A drill plate may detect penetration by a tool or other cutting device. When a penetration of the drill plate occurs, an appropriate signal is provided to detecting electronics. In one embodiment, the drill plate includes a polyvinylidene difluoride (PVDF) film, coated on both sides with a soft and pliable silver conductive ink. As a tool or implement penetrates the drill plate, the silver ink is dragged through the breach and creates an electrical short to the silver ink on the opposite side. The short may be detected by electronics coupled to the conductive inks, across the PVDF film.

According to an embodiment of the present invention, one or more of layers 210a, 210b may incorporate a breakwire pattern. A breakwire pattern is useful for detecting efforts to peel the sensor either apart, and/or from a mounting surface. In one embodiment, the breakwire pattern includes narrow conductors printed onto the surface of a PVDF film. The conductors may be composed of the same silver ink used for the drill plate. The breakwire pattern is designed to be fragile and may be combined with pressure sensitive adhesives and/or other tamper sensitive features so that an attempt to peel the tamper sensor apart or peel it from a mounting surface will break the conductive ink pattern. A small electrical current may be used to monitor the continuity of the breakwire. When the pattern is broken, the current will drop, which may be detected by electronics coupled to the breakwire.

Referring now to FIG. 6, there is shown a multi-layer structure 400 suitable for use as each of tamper resistance layers 210a, 210b. Structure 400 incorporates both drill plate and breakwire components. Layers 405 and 475 are liners, which cover the two outer surfaces of structure 400. Layer 410 may take the form of a thin layer of pressure sensitive adhesive, such as a silicone or acrylic adhesive. Layer 415 is an electrical insulation layer, and may take the form of a thin layer of an acrylic or urethane coating, for example. Layer 420 is a conductive ink layer, composed of silver, for example, formed in a first serpentine pattern deposited on layer 425, which may be composed of a 28 (μm) micron thick, PVDF film. Layer 430 is a thin layer of adhesive, such as a 9458 adhesive, which is commercially available from 3M Corp. Layers 435 and 445 are silver ink layers attached to a 28 micron thick, PVDF film layer 440. Layer 450 is a thin layer of an adhesive, such as a 9458 adhesive, which is commercially available from 3M Corp. Layer 455 is another 28 micron thick, PVDF layer having deposited thereon another silver ink layer 460, forming a second serpentine pattern. Layer 465 is another electrical insulation layer, and may take the form of a thin layer of acrylic coating, for example. And, layer 470 may take the form of a thin layer of a pressure sensitive adhesive, such as a silicone or acrylic adhesive, for example. The layer structure 400 may be laminated together in a conventional manner.

Other tamper resisting structures may be used. For example, one or more of layers 210a, 210b may take the penetration sensor disclosed in U.S. Pat. No. 4,954,811, entitled “PENETRATION SENSOR”, the entire disclosure of which is hereby incorporated by reference as if being set forth in its entirety herein. Other peel-type sensors may be used.

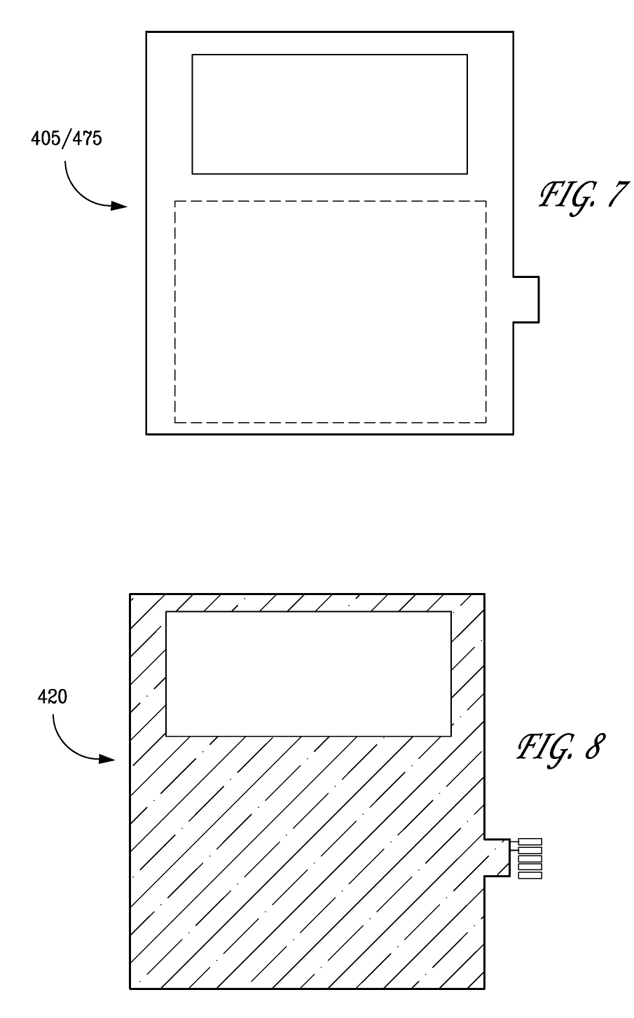

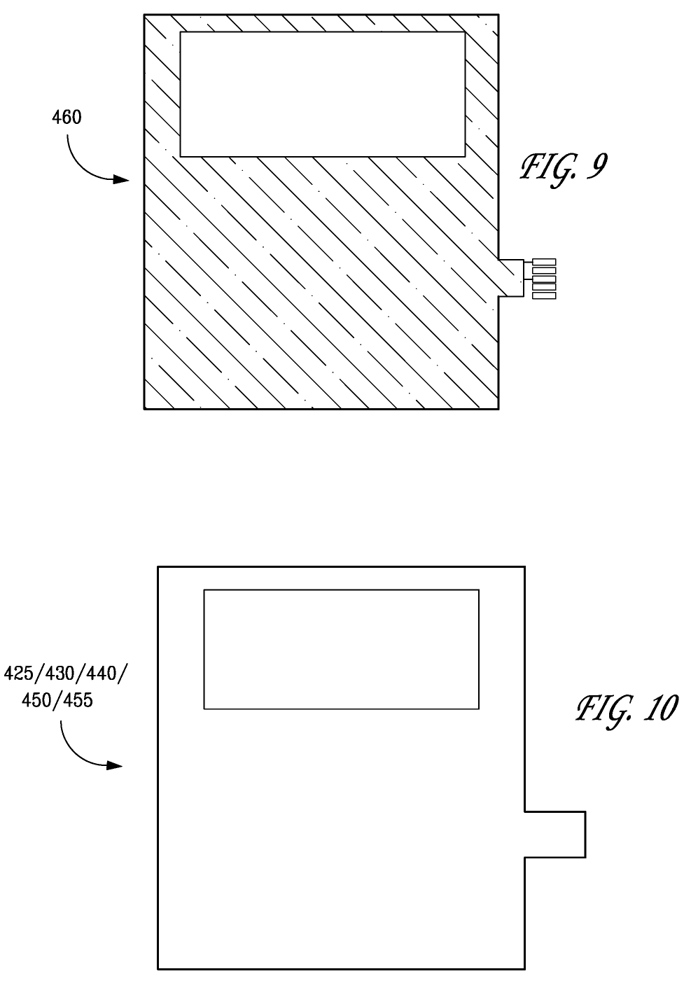

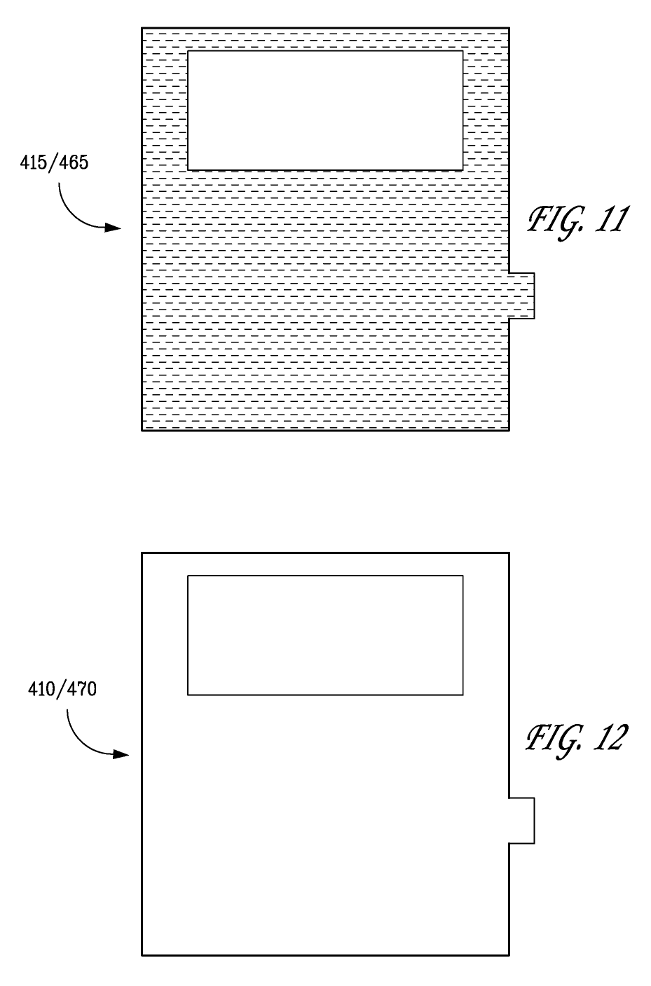

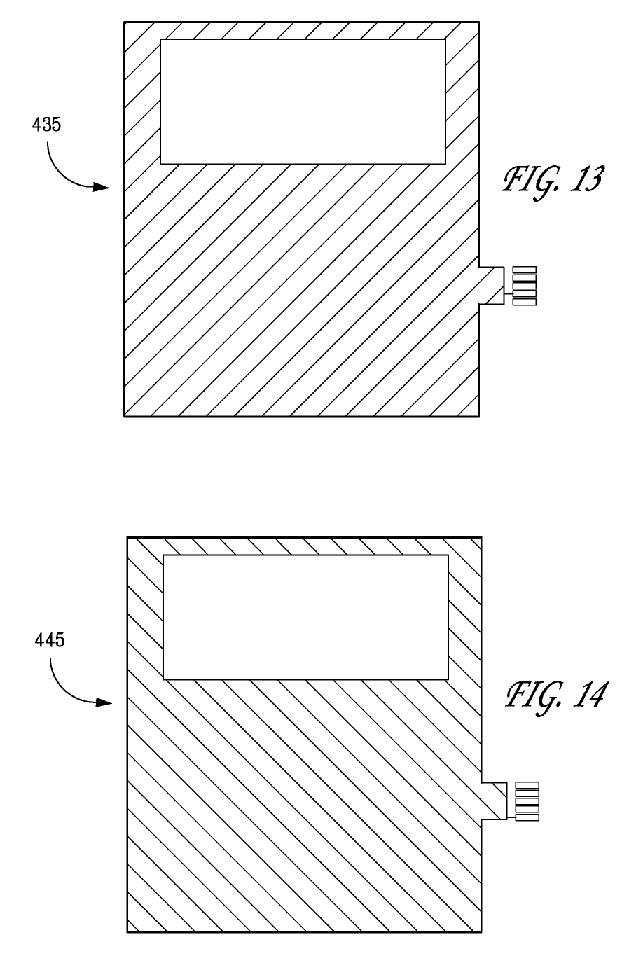

Referring now to FIGS. 7-14, there are shown configurations of the layers of FIG. 6 according to an embodiment of the present invention. Other configurations may be used. FIG. 7 shows a plan view of release liner layers 405, 475. FIG. 8 shows a plan view of silver, serpentine conductor layer 420. FIG. 9 shows a plan view of silver, serpentine conductor layer 460. FIG. 10 shows a plan view of adhesive layers 430, 450 and PVDF layers 425, 440, 455. FIG. 11 shows a plan view of insulating layers 415, 465. FIG. 12 shows a plan view of adhesive layers 410, 470 relative to layers 405, 475. FIG. 13 shows a plan view of first drill layer 435. FIG. 14 shows a plan view of second drill layer 445. Such layers may be deposited and laminated together in a conventional manner.

Referring now to FIG. 15, there is shown an electrical configuration of the layers of FIG. 6, according to an embodiment of the present invention. The non-limiting embodiment 500 of FIG. 15 includes five (5) leads 500 (0-4). Leads 1 and 2 are electrically coupled across serpentine layers 420, 460. Lead 3 is coupled to drill layer 435. Lead 4 is coupled to drill layer 445. Lead 0 is coupled between layers 420, 460. By checking for continuity between leads 0, 1 and 2, peel-type tampering may be detected. By checking for shorts between leads 3 and 4, penetration-type tampering may be detected. PVDF layer 440 (see FIG. 6) is also shown. An indicator, such as an audible and/or visual indication, of tampering may be provided responsively to signals sensed using leads 0-4. Alternatively, or in addition thereto, a device incorporating circuit 500, such as a POS device and/or an ATM machine may be selectively disabled responsively to signals sensed using leads 0-4. In an exemplary embodiment, a device incorporating circuit 500 may be disabled by zeroizing or resetting the memory of the device and/or storage registers of the device containing sensitive electronic data, responsive to signals sensed using leads 0-4. For example, software stored in a storage medium in the device, when executed by a processor of the device, may cause the processor to execute the steps of: checking for a condition indicating either peel-type tampering or penetration-type tampering; responsive to detecting such a condition, causing a speaker or other sound emitting device to emit sound, and/or causing a lamp or other light-emitting device, to light; or to cause one or more memory locations or storage registers to zeroize or reset thereby disabling or deactivating the device.

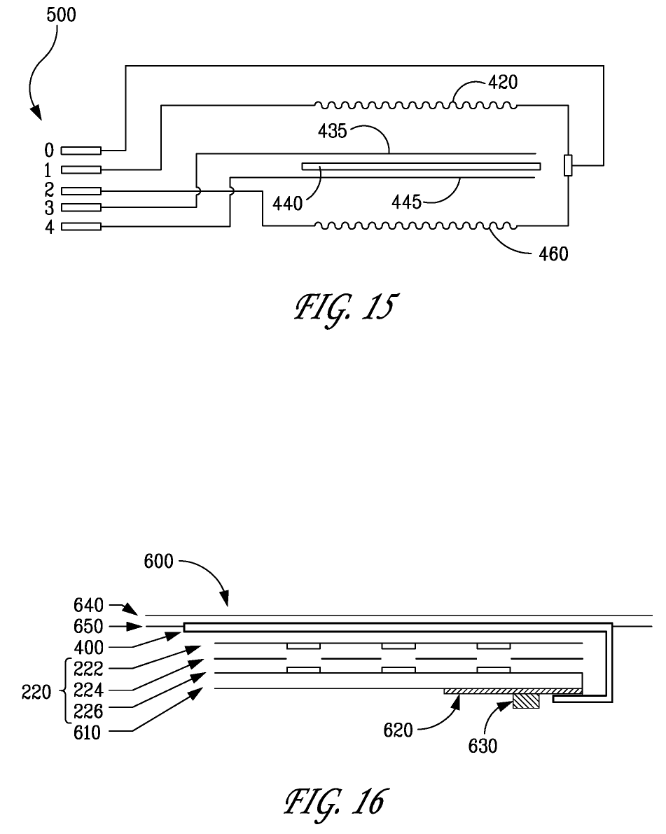

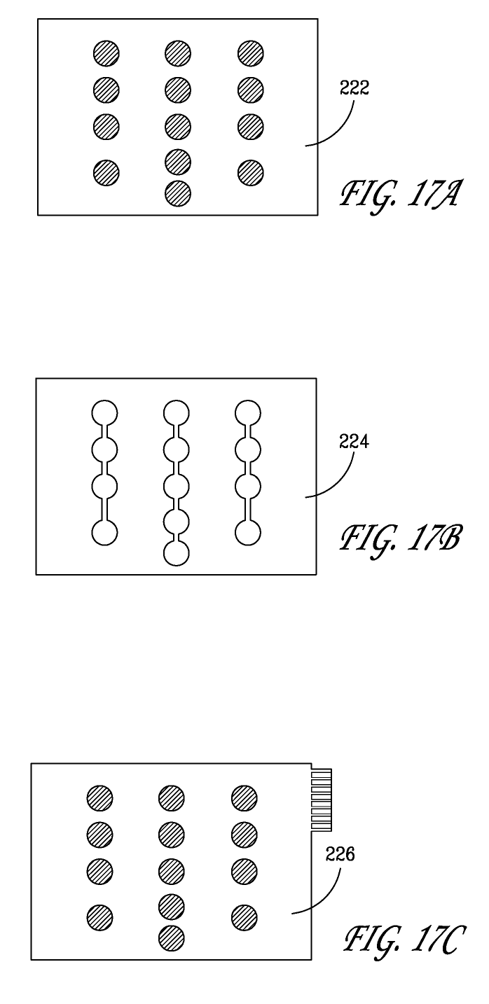

Referring now to FIG. 16, there is shown a cross-section view of a tamper resistant membrane switch keypad assembly 600 according to an embodiment of the present invention. Assembly 600 is well suited for use with keypad 110 in conjunction with a POS or ATM terminal. Assembly 600 includes sensor 220 and tamper resistance multi-layer structure 400. Referring now also to FIGS. 17a-17c, there are shown configurations of the layers of sensor 220 according to an embodiment of the present invention. In the illustrated embodiment, sensor 220 includes a top circuit layer 222, a spacer layer 224 and a bottom circuit layer 226. Layers 222, 226 may incorporate conductive circuit traces analogous to those discussed in connection with FIG. 5. Layers 222, 226 may each take the form of an about 4 mil thick Mylar based circuit, spaced apart by an about 7 mil thick 7957 adhesive, which is available from 3M Corporation.

Referring still to FIG. 16, assembly 600 may additionally include and be backed by an about 5 mil thick 468 MP adhesive layer 610, which is also available from 3M Corporation. The 468 MP adhesive layer 610 is adhered in the illustrated embodiment to a flexible circuit board 620, having an electrical connector 630. In the illustrated embodiment, assembly 600 additionally includes overlay and spacer layers 640, 650.

Tamper resistance multi-layer structure 400 is coupled to circuit 620, both mechanically (such as via an adhesive) and electrically (see, e.g., FIG. 15). Tamper resistance multi-layer structure 400 is folded around sensor 220 and overlays sensor 220.

Referring now also to FIG. 18, there is shown a plan view of the front of assembly 600 according to an embodiment of the present invention. Overlay 640 may be provided with embossed keys 642 to provide tactile feedback. Overlay 640 may be composed of vinyl or polycarbonate, for example. A transparent window 644 is provided, and a suitable display, such as an LCD based display, may be positioned so as to be viewable there-through (See, e.g., display 40, FIGS. 1-3).

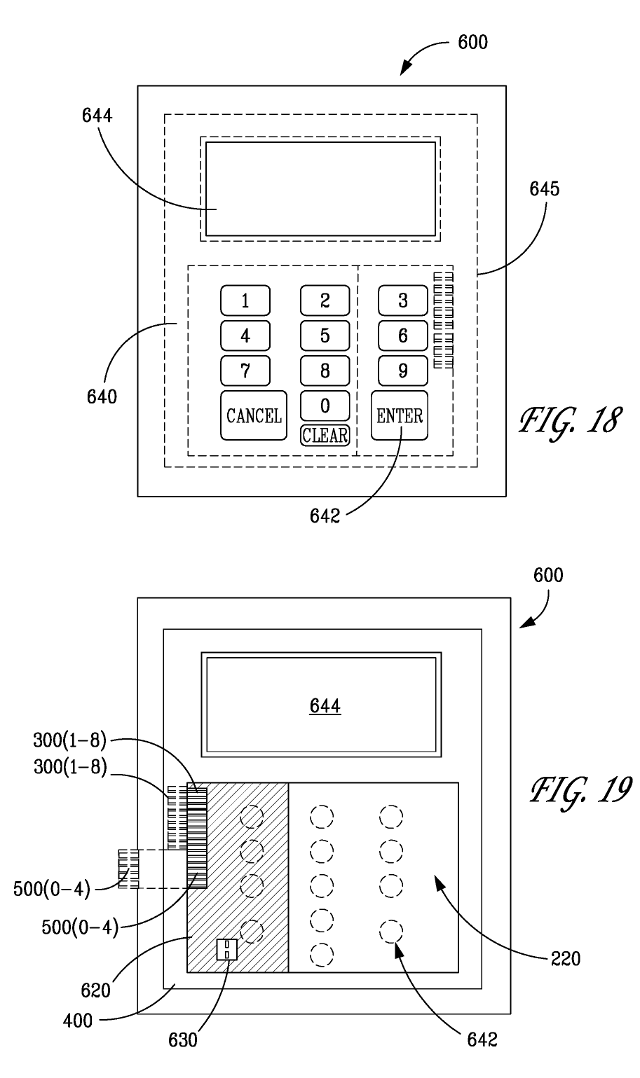

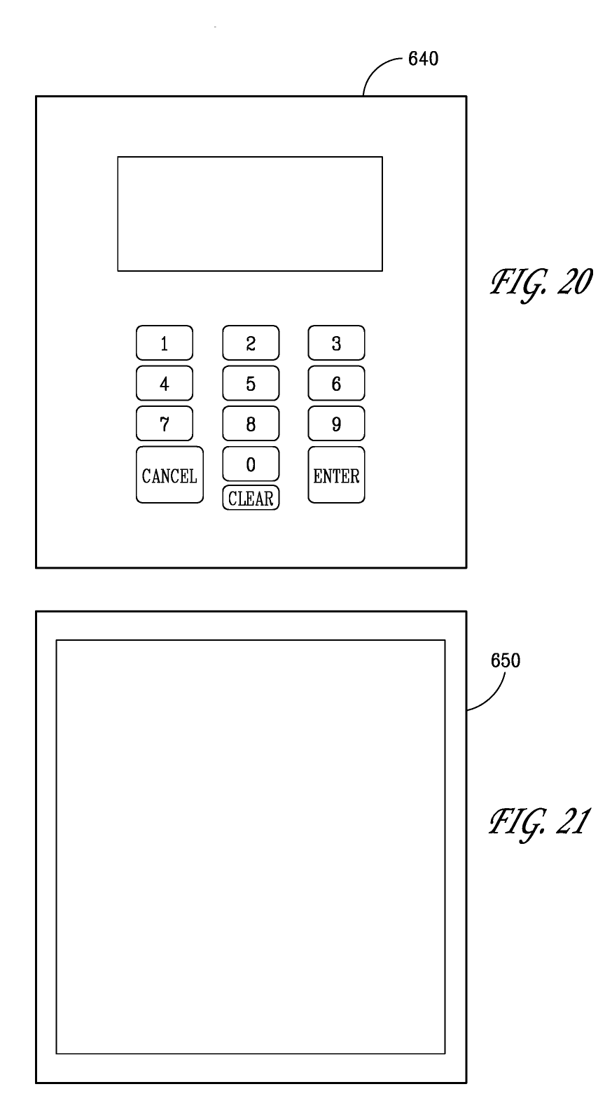

Referring now to FIG. 19, there is shown a plan view of the rear of assembly 600 according to an embodiment of the present invention. Again shown are window 644, sensor 220, keys 642, connector 630, tamper sensor 400, flex circuit 620, sensor 400 leads (FIG. 5, 500(0-4)) both before and after folding, and keypad leads (FIG. 3, 300(1-8)) both before and after folding.

Referring now to FIGS. 20 and 21, there are shown plan views of an overlay 640 and adhesive 650 (see also FIG. 16) according to embodiments of the present invention. It is understood that the tamper film consists of an area smaller than that of the overlay. Furthermore, the adhesive 650 as shown in FIG. 21 comprises a frame structure having a window portion sized to accommodate the thickness of the tamper sensor structure 400 such that the outer surface of the overlay is substantially flat. The configuration of the adhesive frame, overlay and tamper sensor provides a robust defense from attack at the edges of the overlay as well as from the top or outside surface of the overlay.

It will be apparent to those skilled in the art that modifications and variations may be made in the apparatus and process of the present invention without departing from the spirit or scope of the invention. It is intended that the present invention cover the modification and variations of this invention provided they come within the scope of the appended claims and their equivalents.

What is claimed is:

1. A tamper resistant user interface device comprising:
a substantially planar sensor, said sensor comprising a plurality of user activated membrane switches; and
at least one multilayer structure folded around and overlaying said planar sensor, said structure comprising at least one layer to detect tampering with said sensor.

2. The device of claim 1, wherein said sensor is in the form of a keyboard or a keypad.

3. The device of claim 1, wherein said multilayer structure further comprises a plurality of serpentine conductor layers.

4. The device of claim 1, wherein said plurality of membrane switches comprises a circuit printed on a thermoplastic polymer resin.

5. The device of claim 1, wherein said multilayer structure further comprises a drill plate, said drill plate comprising a film, said film coated on both sides with silver conductive ink, wherein when said film is penetrated, an electrical short is created between said silver conductive ink on both sides.

6. The device of claim 5, wherein said film comprises a polyvinylidene difluoride (PVDF) film.

7. The device of claim 1, wherein said multilayer structure further comprises a breakwire pattern, said pattern comprising:
a film; and
a plurality of narrow conductors printed on said film,
wherein said breakwire pattern is adapted to receive a small electrical current, which current will be interrupted if said breakwire pattern is broken.

8. The device of claim 7, wherein said film comprises a polyvinylidene difluoride (PVDF) film.

9. The device of claim 1, wherein said multilayer structure comprises:
a first outer liner layer;
a first thin layer of pressure sensitive adhesive layer adjacent to said first outer liner layer;
a first electrical insulation layer adjacent to said first thin layer of pressure sensitive adhesive layer;
a first PVDF film;
a first conductive ink layer interposed between said first electrical insulation layer and said first PVDF film;
a second adhesive layer adjacent to said first PVDF film;
a second PVDF film;
second and third layers of conductive ink layers disposed on either side of said second PVDF film;
a third adhesive layer;
a third PVDF film;
a second electrical insulation layer;
a fourth conductive ink layer interposed said third PVDF layer and said second electrical insulation layer;
a fourth pressure sensitive adhesive layer adjacent to said second electrical insulation layer; and
a second outer liner layer adjacent to said fourth pressure sensitive adhesive layer.

10. The device of claim 2, wherein said keyboard or keypad is disposed in an electronic transaction machine.

11. An electronic transaction assembly comprising a circuit for detecting tampering with a user interface containing a sensor, said circuit comprising:
first and second drill layers on either side of a substantially planar sensor;
first and second electrical leads electrically coupled to said first and second drill layers respectively;
first and second serpentine conductive layers adjacent to said first and second drill layers respectively;
third and fourth electrical leads electrically coupled across said first and second serpentine conductive layers respectively; and
a fifth electrical lead coupled between said first and second conductive layers;
wherein, peel-type tampering is detected by checking continuity between said third and fifth leads and between said fourth and fifth leads and penetration-type tampering is detected by checking for shorts between said first and second leads connected to said first and second drill layers respectively.

12. The assembly of claim 11, further comprising an indicator, said indicator adapted to provide an indication of tampering responsive to signals sensed using said first, second, third, fourth and fifth leads.

13. The assembly of claim 12, wherein said indicator provides an audible indication.

14. The assembly of claim 12, wherein said indicator provides a visual indication.

15. The assembly of claim 11, wherein said circuit is selectively disabled responsively to signals sensed using said first, second, third, fourth, and fifth leads.

16. The assembly of claim 11, wherein said assembly is a point of sale card reader.

17. A method for detecting tampering with a sensor, said method comprising the steps of:
checking for electrical shorts between first and second electrical leads coupled to first and second drill layers disposed on either side of a substantially planar sensor of a keyboard or keypad of an electronic transaction machine; and
checking for a break in continuity between third and fourth electrical leads, and between fifth and fourth electrical leads, wherein said third and fifth electrical leads are electrically coupled across first and second conductive layers adjacent to said first and second drill layers respectively and said fourth electrical lead is coupled between said first and second conductive layers.

18. The method of claim 17, further comprising providing a visual or audible indicator in response to detection of said electrical short or said break in continuity.

19. The method of claim 17, further comprising disabling said electronic transaction machine in response to detection of said electrical short or said break in continuity.
